(19) United States
(12) Patent Application Publication
(10) Pub. No.: US 2026/0090408 A1
(43) Pub. Date: Mar. 26, 2026

(54) HIGH-POWER ELECTRONIC PACKAGE WITH ELECTRICALLY ISOLATED HEATSINK

(71) Applicant: Navitas Semiconductor Limited, Dublin (IE)

(72) Inventors: Maria Cristina ESTACIO, Lapulapu City (PH); Oseob JEON, Seoul (KR)

(73) Assignee: Navitas Semiconductor Limited, Dublin (IE)

(21) Appl. No.: 19/335,866

(22) Filed: Sep. 22, 2025

Related U.S. Application Data
(60) Provisional application No. 63/697,231, filed on Sep. 20, 2024.

(51) Int. Cl. H01L 23/498; H01L 23/00

(52) U.S. Cl. CPC H10W 70/479; H10W 72/07636; H10W 90/766

(57) ABSTRACT

An electronic device may include an electrically conductive base, an electrically insulative layer attached to the base, and first and second exterior terminals at an exterior surface. A first electrical conductor may be attached to the electrically insulative layer and electrically connected to the first exterior terminal. A semiconductor die may have a first contact at a bottom surface electrically connected to the first electrical conductor, and a second contact at a top surface. A second electrical conductor may be attached to the top surface of the semiconductor die and may be electrically connected to the second exterior terminal. An encapsulant may at least partially encapsulate the electrically conductive base, the first and second exterior terminals, the electrically insulative layer, the first electrical conductor, the semiconductor die, and the second electrical conductor.

### CROSS-REFERENCES TO OTHER APPLICATIONS

This application claims priority to U.S. provisional patent application Ser. No. 63/697,231 for “HIGH-POWER ELECTRONIC PACKAGE WITH ELECTRICALLY ISOLATED HEATSINK” filed on Sep. 20, 2024, which is hereby incorporated by reference in entirety for all purposes.

### FIELD

The described embodiments relate generally to packaged electronics containing one or more semiconductor dies. More particularly, the present embodiments relate to a high-power electronic package with an electrically isolated heatsink that provides cooling for the one or more semiconductor dies.

### BACKGROUND

Electronic devices such as computers, servers, and televisions, among others, employ numerous packaged semiconductor devices. Such semiconductor devices require specialized electronic packages to accommodate unique physical configurations and performance requirements. New electronic package designs and manufacturing techniques may be required to meet the needs of some semiconductor devices.

### SUMMARY

In some embodiments, an electronic device is disclosed. The electronic device includes an electrically conductive base; a first exterior terminal at an exterior surface of the electronic device; a second exterior terminal at the exterior surface of the electronic device; an electrically insulative layer attached to the electrically conductive base; a first electrical conductor attached to the electrically insulative layer and electrically connected to the first exterior terminal; a semiconductor die having a first contact at a bottom surface and second contact at a top surface, wherein the semiconductor die is attached to the first electrical conductor such that the first contact is electrically connected to the first electrical conductor; a second electrical conductor attached to the top surface of the semiconductor die such that the second contact is electrically connected to the second exterior terminal; and an encapsulant at least partially encapsulating the electrically conductive base, the first exterior terminal, the second exterior terminal, the electrically insulative layer, the first electrical conductor, the semiconductor die, and the second electrical conductor.

In some embodiments, the first contact is a drain terminal of the semiconductor die and the second contact is a source terminal of the semiconductor die. In some embodiments, the semiconductor die is a transistor. In some embodiments, the semiconductor die includes gallium nitride, silicon carbide, or silicon. In some embodiments, the first electrical conductor and the second electrical conductor are semi-planar layers of metal. In some embodiments, the electrically insulative layer includes a ceramic. In some embodiments, a length and a width of a die attach region of the first electrical conductor are larger than a respective length and width of the semiconductor die. In some embodiments, the semiconductor die includes a kelvin terminal.

In some embodiments, an electronic device is disclosed. The electronic device includes a first exterior terminal at an exterior surface of the electronic device; a second exterior terminal at the exterior surface of the electronic device; an insulative layer; a first conductor attached to the insulative layer and electrically connected to the first exterior terminal; a semiconductor die having a first contact at a bottom surface and a second contact at a top surface, the first contact is attached to the first conductor; a second conductor attached to the second contact and electrically connected to the second exterior terminal; and an encapsulant at least partially encapsulating the insulative layer, the first conductor, the semiconductor die, and the second conductor.

In some embodiments, the first and second conductors are semi-planar layers of metal. In some embodiments, the insulative layer includes a ceramic. In some embodiments, a length and a width of a die attach region of the first conductor are larger than a respective length and width of the semiconductor die. In some embodiments, a method of forming an electronic device is disclosed. The method includes forming a first terminal; forming a second terminal; forming an insulative layer; forming a first conductor and attaching the first conductor to the insulative layer and to the first terminal; forming a semiconductor die having a first contact at a bottom surface and a second contact at a top surface; attaching the first contact to the first conductor; forming a second conductor; attaching the second conductor to the second contact and to the second terminal; and forming a body of the electronic device using an encapsulant that at least partially encapsulates the insulative layer, the first conductor, the semiconductor die, and the second conductor. In some embodiments in the method of forming the electronic device, the semiconductor die is a transistor. In some embodiments in the method of forming the electronic device, the semiconductor die includes gallium nitride, silicon carbide, or silicon.

### BRIEF DESCRIPTION OF THE DRAWINGS

FIG. 1A is a partially transparent top view of an assembled single-chip electronic device with an electrically isolated heatsink according to some aspects of the present application;

FIG. 1B is a cross-section of the electronic device shown in FIG. 1A;

FIG. 1C is an enlarged view a portion of the electronic device shown in FIG. 1B;

FIG. 2A is a flow chart of a process for assembling a single-chip electronic device with an electrically isolated heatsink according to some aspects of the present application;

FIGS. 2B-2F are simplified sequential plan views of a formation of the single-chip electronic device according to the process described in FIG. 2A.

FIG. 3A is a top partially transparent top view of an assembled multi-chip electronic device with an electrically isolated heatsink according to some aspects of the present application;

FIG. 3B is a cross-section of the electronic device shown in FIG. 3A;

FIG. 4A is a flow chart of a process for assembling a multi-chip electronic device with an electrically isolated heatsink according to some aspects of the present application;

FIGS. 4B-4G are simplified sequential plan views of a formation of the multi-chip electronic device according to the process described in FIG. 4A.

FIG. 5A is a partially transparent top view of an assembled isolated half-bridge electronic device with an electrically isolated heatsink according to some aspects of the present application;

FIG. 5B is a cross-section of the electronic device shown in FIG. 5A; and

FIG. 6 is a partially transparent top view of an assembled isolated gallium nitride (GaN)-based half-bridge electronic device with an electrically isolated heatsink according to some aspects of the present application.

### DETAILED DESCRIPTION OF THE INVENTION

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

Techniques disclosed herein relate generally to electronic devices. More specifically, techniques disclosed herein relate to electronic devices that include one or more semiconductor dies enclosed within an electronic package where the electronic package includes an exterior heatsink that enables thermal energy to be dissipated from the one or more semiconductor dies.

More specifically, in some embodiments the electronic device may include a semiconductor die (e.g., transistor) that may be positioned between two semi-planar electrical conductors within an encapsulated package structure. The semiconductor die may include electrical contacts at both top and bottom surfaces (e.g., forming source and drain contacts of a transistor) that may enable electrical connections to external terminals of the device and enable thermal dissipation via the electrical conductors. An electrically conductive base may serve as a foundation for the package structure and may also function as a thermal pathway for heat dissipation. An electrically insulative layer may be positioned between the conductive base and one or more of the electrical conductors to provide electrical isolation while maintaining high thermal conductivity. The encapsulant material may surround and protect the internal components while allowing the conductive base to remain exposed at the exterior surface to function as an integrated heatsink.

The configuration may enable efficient thermal energy transfer from the semiconductor die to the exterior environment through the conductive base structure and through the electrical conductors. The semiconductor die may comprise various materials such as gallium nitride, silicon carbide, or silicon, depending on the specific application requirements. The electrical conductors may be formed as semi-planar metal layers that may provide reliable electrical connections while maintaining compact package dimensions. This integrated approach may eliminate the need for separate heatsink components and may reduce overall system complexity while improving thermal performance of the electronic device.

Several illustrative embodiments will now be described with respect to the accompanying drawings, which form a part hereof. The ensuing description provides embodiment(s) only and is not intended to limit the scope, applicability, or configuration of the disclosure. Rather, the ensuing description of the embodiment(s) will provide those skilled in the art with an enabling description for implementing one or more embodiments. It is understood that various changes may be made in the function and arrangement of elements without departing from the spirit and scope of this disclosure. In the following description, for the purposes of explanation, specific details are set forth in order to provide a thorough understanding of certain inventive embodiments. However, it will be apparent that various embodiments may be practiced without these specific details. The figures and description are not intended to be restrictive. The word “example” or “exemplary” is used herein to mean “serving as an example, instance, or illustration.” Any embodiment or design described herein as “exemplary” or “example” is not necessarily to be construed as preferred or advantageous over other embodiments or designs.

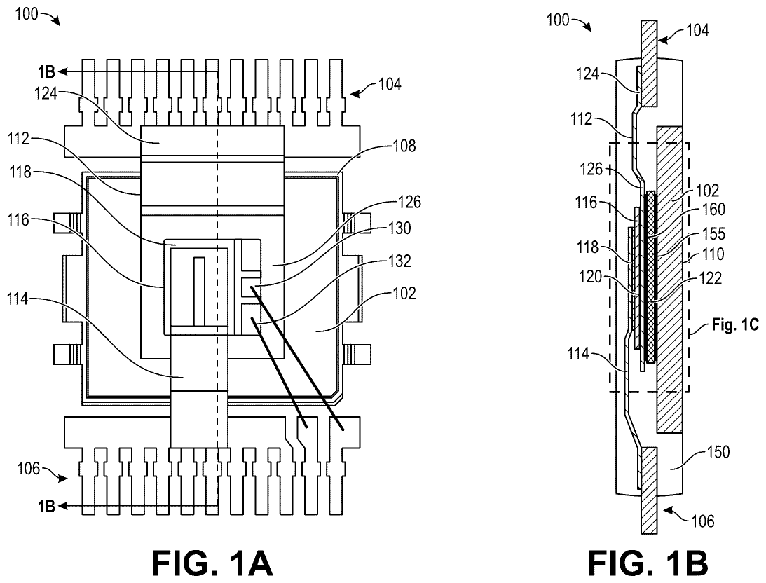

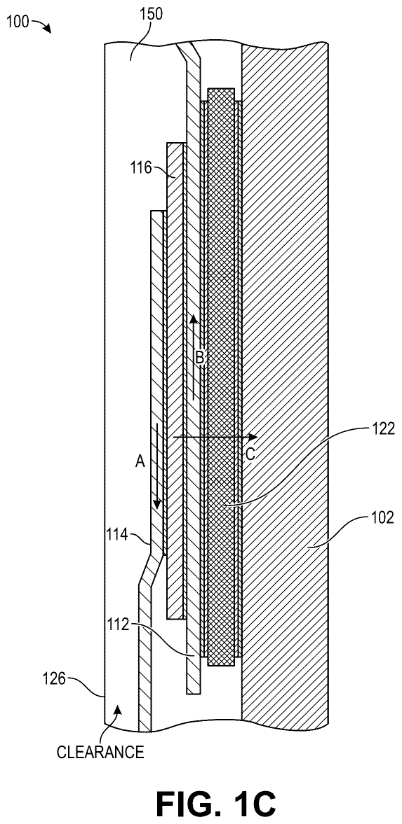

FIG. 1A is a partially transparent top view of an assembled electronic device 100 with an electrically isolated heatsink, according to some embodiments of the present application. As shown in FIG. 1A, the electronic device 100 can include a thermally conductive base 102. The thermally conductive base 102 can include a first side 108 opposite a second side 110 (not shown in FIG. 1A) and may generally be referred to as a portion of a leadframe. However, in other embodiments the conductive base 102 may be an electrically conductive portion of a substrate that may include one or more layers of organic laminate interspersed with one or more metallic layers. A first group of exterior terminals 104 can be positioned along a first side of the electronic device 100 and may be a portion of the leadframe. The first group of exterior terminals 104 is shown to include eleven terminals, however it can include any suitable number of terminals including a single terminal. A second group of exterior terminals 106 can be positioned along a second side of the electronic device 100 and may be a portion of the leadframe. The second group of exterior terminals 106 is shown to include nine terminals, however it can include any suitable number of terminals including a single terminal. The electronic device 100 can include an electrically insulative layer (not shown in FIG. 1A) that is attached to the conductive base 102 using, but not limited to, soldering, sintering, conductive or non-conductive epoxy, etc. A first semi-planar conductor 112 can have a first flat portion 126 attached to the electrically insulative layer (not shown in FIG. 1A) using, but not limited to, soldering, sintering, conductive or non-conductive epoxy, etc. The first semi-planar conductor 112 may be formed from any electrically conductive material including but not limited to, copper, copper alloys, silver, gold or aluminum. A second flat portion 124 of the first semi-planar conductor 112 can be attached to the first group of exterior terminals 104 using, but not limited to, soldering, sintering, conductive or non-conductive epoxy, etc.

The electronic device 100 can further include a semiconductor die 116 that may include one or more transistors and may be made from silicon-carbide, gallium nitride, silicon, diamond or other suitable semiconductor material. The semiconductor die 116 can be attached to a top surface of the first flat portion 126 of the first semi-planar conductor 112 using, but not limited to, soldering, sintering, conductive or non-conductive epoxy, etc. The semiconductor die 116 can include a source terminal 118 at a top surface, a gate terminal 130 at the top surface, a kelvin sense terminal 132 at the top surface and any other suitable terminals at the top surface and a drain terminal (not shown in FIG. 1A) at a bottom surface. The drain terminal can be electrically coupled to the first flat portion 124 of the first semi-planar conductor 112. Thus, the first semi-planar conductor 112 can electrically connect the drain terminal to the first group of exterior terminals 104. A second semi-planar conductor 114 can electrically connect the source terminal 118 to the second group of exterior terminals 106. The second semi-planar conductor 114 may be formed from any electrically conductive material including but not limited to, copper, copper alloys, silver, gold or aluminum.

One or more wirebonds or other type of electrical conductors can couple the gate terminal 130, kelvin terminal 132, etc. of the semiconductor die 116 to one or more exterior terminals. The components of the electronic device 100 can be at least partially encapsulated within a dielectric encapsulant 150 (not shown in FIG. 1A). The electronic device 100 may have a length and a width that are between 1 and 20 millimeters, between 3 and 10 millimeters or between 4 and 6 millimeters.

FIG. 1B is a simplified cross-section of electronic device 100 shown in FIG. 1A. As shown in FIG. 1B the electronic device 100 includes an electrically insulative layer 122 having a bottom surface 155 attached to conductive base 102 and a top surface 160 attached to first semi-planar conductor 112. The electrically insulative layer 122 can be formed from a ceramic material, such as, but not limited to, alumina, aluminum nitride, beryllium oxide, etc. The electrically insulative layer 122 can include one or more layers of metal plating. While the electrically insulative layer 122 is shown in FIG. 1B with a layer of plated copper on both sides, the electrically insulative layer 122 can include a single layer of plated metal or plated metal layers may be absent. The electrically insulative layer 122 can have a thickness between 20 to 300 microns and can have a total thickness (including two plated metal layers) between 100 to 500 microns.

As further shown in FIG. 1B, semiconductor die 116 is positioned between first semi-planar conductor 112 and second semi-planar conductor 114, which are both metallic and have relatively high thermal conductivity. Further semiconductor die 116 is thermally coupled to base 102 via first semi-planar conductor 114 and insulative layer 122 (which generally has a relatively high thermal conductivity). Therefore, thermal energy is efficiently dissipated from semiconductor die 116 to first group of exterior leads 104 via first semi-planar conductor 112, to second group of exterior leads 106 via second semi-planar conductor 114 and to base 102. Insulative layer 122 electrically insulates the drain of semiconductor die 116 (which is attached to first semi-planar conductor 112) from the base 102 so the base can conduct thermal energy from the semiconductor die 116 while being electrically isolated from the semiconductor die 116.

In some embodiments a pad area of second flat portion 126 can be greater than a surface area of the semiconductor die 116 and may assist in spreading thermal energy from the semiconductor die to reduce the thermal power density (and the associated drop in temperature) of the thermal energy conducted through insulative layer 122. In further embodiments the surface area of the base 102 may be larger than a surface area of the insulative layer 122 and/or the semiconductor die 116 to similarly reduce the thermal power density of the thermal energy conducted to an exterior heat exchanger that is thermally coupled to the base via a thermal interface material. The electronic device 100 can be at least partially encapsulated in a dielectric polymer material 150. A clearance can be defined from a top of the second semi-planar conductor 114 to an outer surface of dielectric polymer material that may be between 100 and 1000 microns.

FIG. 1C is an enlarged view of a portion of the cross-section of electronic device 100 illustrated in FIG. 1B. As shown in FIG. 1C, various heat dissipation paths are shown that enable the semiconductor die 116 to dissipate thermal energy. For example, heat can be dissipated away from semiconductor die 116 along lateral path A through second semi-planar conductor 114. Heat can also be dissipated away from the semiconductor die 116 along lateral path B through first semi-planar conductor 112. Additionally, heat can flow away from the semiconductor die 116 along a perpendicular path C that passes through the first semi-planar conductor 112, electrically insulative layer 122, and conductive base 102. In further embodiments an additional perpendicular path may be formed from the semiconductor die 116 through second semi-planar conductor 114 and out of the top of the package using e.g., thinned mold compound 150 and/or a thermally conductive insert thermally coupled to the second semi-planar conductor.

In some embodiments the semiconductor die 116 may be formed from gallium nitride and may have a source terminal at a top surface that is electrically connected to one or more exterior leads via a semi-planar conductor or other electrical conductor. The gallium nitride die may be attached directly to a semi-planar conductor or may be attached to an insulative layer that is attached to the base where the source terminal is then connected to a metal layer formed on the insulative layer (or the source can be optionally connected to the base when the die is attached to the insulative layer). In various embodiments the semiconductor die may be a bidirectional switch (formed from gallium nitride, silicon carbide, silicon or other suitable material) that is attached to an insulative layer which is attached to the base such that the base is electrically isolated. In some embodiments the electronic device may be configured as what is commonly referred to as a surface mountable device (SMD) having formed electrical leads, solder pads (e.g., formed on the bottom of a substrate), through-hole or any other suitable configuration. In some embodiments the electronic device may be attached to a mating circuit board where the base is a top surface of the device (such that it can be interfaced with a separate heat sink) and the leads are at a bottom surface of the device such that they can be electrically connected to the mating circuit board. In various embodiments the base may also be positioned at a bottom surface of the electronic device such that it may interface directly with the mating circuit board and transfer thermal energy into the circuit board.

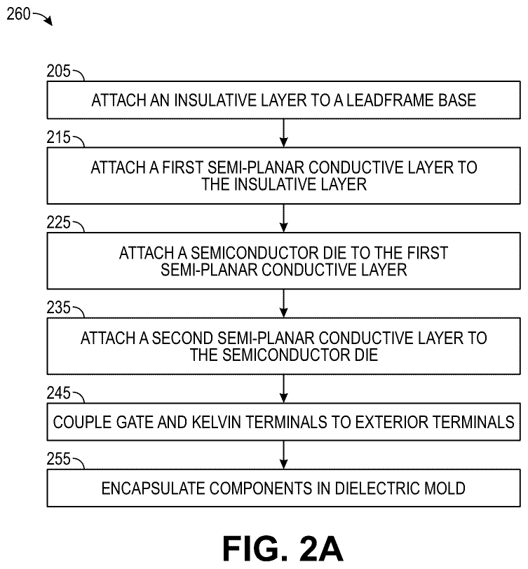

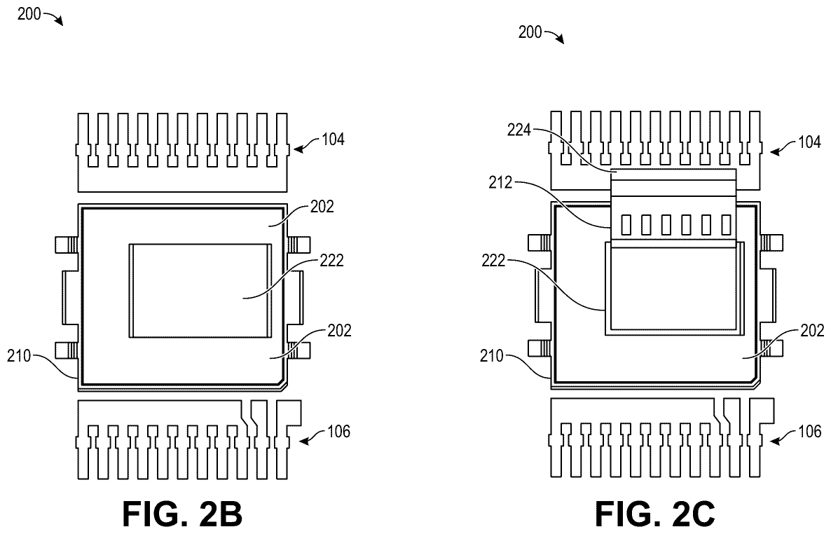

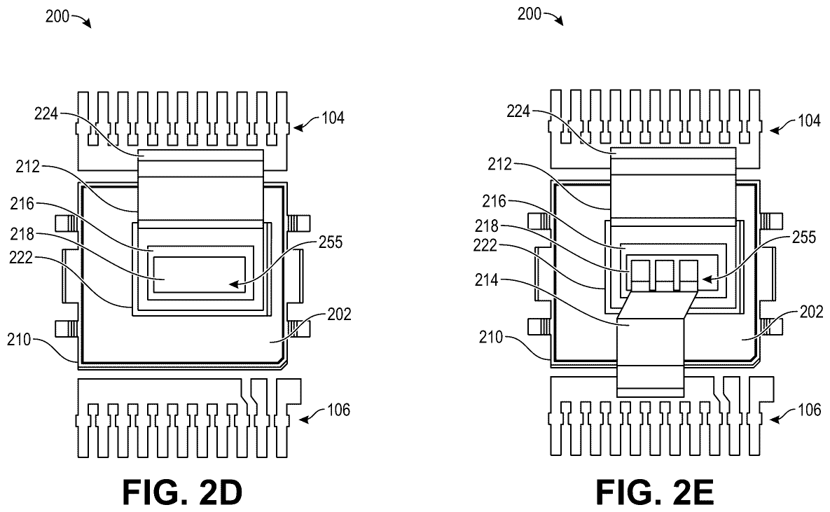

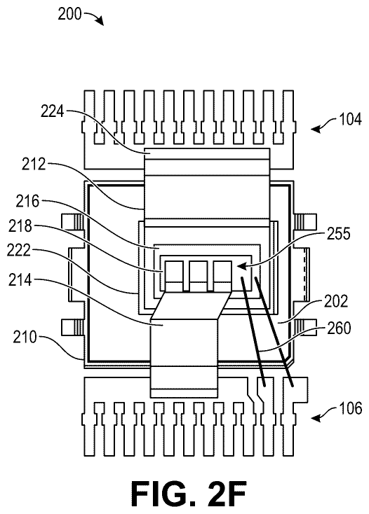

FIG. 2A illustrates steps associated with a method 260 of forming an electronic device 200 according to embodiments of the disclosure. FIGS. 2B-2F illustrate simplified plan views of the formation of the electronic device 200 according to method 260 described in FIG. 2A. Electronic device 200 comprises similar components as described in FIGS. 1A-1C, wherein like numerals correspond to like components. Electronic device 200 may be or may include any of the components, features, or characteristics of any of the electronic devices previously described (e.g., electronic device 100), and the features of electronic device 200 may be included in the electronic devices previously discussed.

Now referring to FIG. 2A, in a first step 205 of the method 260 a leadframe (including a base 202) is formed and an electrically insulative layer 222 is attached to the base 202 via solder, sintering, epoxy or other suitable method. Additional solder paste can be dispensed on a top surface of the electrically insulative layer and on the first group of exterior leads.

In a second step 215 of the manufacturing process 260, a first semi-planar conductor is attached to the insulative layer and to the first group of exterior leads via, for example, a first reflow step. As shown in FIG. 2C, first semi-planar conductor 212 is attached to the insulative layer 222 and to the first group of exterior leads 104 via, for example, a first reflow step. In a third step 225 of the manufacturing process 260, a semiconductor die is attached to a top surface of the first semi-planar conductor. As shown in FIG. 2C, a semiconductor die 216 is attached to a top surface of the first semi-planar conductor 212 via soldering, sintering or other suitable process. Semiconductor die 216 includes a source terminal 218 and a gate terminal 255.

In a fourth step 235 of the manufacturing process 260, a second semi-planar conductor is attached to the semiconductor die via, for example, a second reflow step. As shown in FIG. 2E a second semi-planar conductor 214 is attached to the source terminal 218 of the semiconductor die 216 via, for example, a second reflow step. The second reflow step can be similar to the first reflow step (e.g., can be performed simultaneously and/or at a similar temperature using a similar solder alloy) or can involve different parameters such as a different reflow temperature and/or different solder alloys. The first semi-planar conductor 212 can electrically connect a drain terminal of the semiconductor die 216 to the first group of exterior terminals 104. The second semi-planar conductor 214 can electrically connect the source terminal 218 of the semiconductor die 216 to the second group of exterior terminals 160. A fifth step 245 of the manufacturing process 260, can include a wire bonding process that electrically couples the gate terminal and kelvin terminals of the semiconductor die to exterior terminals. As shown in FIG. 2F, wirebonds 260 electrically couple the gate terminal 255 and kelvin terminals of the semiconductor die 216 to exterior terminals. A sixth step 255 of the manufacturing process 260 can include encapsulating one or more features in a dielectric mold material, then trimming and forming the exterior leads.

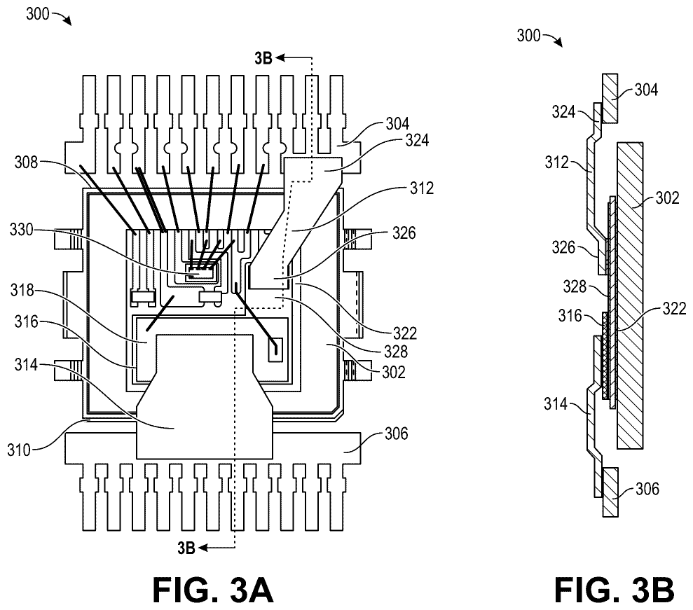

FIG. 3A is a partially transparent top view of a multi-chip electronic device 300 that has an electrically isolated heatsink, according to some aspects of the present application. The multi-chip device 300 can include features described for other electronic devices in this application, such as the features of single-chip electronic devices 100 and 200 described above. The multi-chip electronic device 300 can include an electrically conductive base 302. The electrically conductive base 302 can include a first side 308 and a second side 310. A first group 304 of exterior terminals can be positioned adjacent to the first side 308. The first group 304 of exterior terminals is shown to include three terminals in FIG. 3A, however the first group 304 of exterior terminals can include any number of terminals including a single terminal. Additionally, the multi-chip electronic device 300 can include an electrically insulative layer 322 that is attached to the conductive base 302. A metal layer 328 can be formed on top of the electrically insulative layer 322. The metal layer 328 can be a patterned layer of copper that has a thickness between 20 to 200 microns. A first semi-planar conductor 312 can be attached on a first flat portion 324 to the metal layer 328 above the electrically insulative layer 322. A second flat portion 326 of the first semi-planar conductor 312 can be attached to the first group 304 of exterior terminals.

The multi-chip electronic device 300 can further include a first semiconductor die 316. The first semiconductor die 316 can be attached to a portion of the metal layer 328. The first semiconductor die 316 can include a top surface 318 that can be a source terminal. A second group 306 of exterior terminals can be positioned adjacent to the second side 310 of the conductive base 302. The second group 306 of exterior terminals is shown to include eleven terminals in FIG. 3A, however the second group of exterior terminals can include any number of terminals including a single terminal. A second semi-planar conductor 314 can electrically connect the top surface 318 of the first semiconductor die 316 to the second group 306 of exterior terminals. The first semiconductor die 316 can also include a drain terminal (not shown in FIG. 3A) on a bottom surface of the first semiconductor die 316. The first semi-planar conductor 312 can electrically connect the drain terminal to the first group 304 of exterior terminals via the metal layer 328. The multi-chip electronic device 300 can include additional semiconductor dies, such as second semiconductor die 330 and/or passive electronic components (e.g., resistor, capacitor, diode, etc.). In some embodiments second semiconductor die 330 may be formed from a different semiconductor material than first semiconductor die 316. In one example first semiconductor die includes a first power transistor and is made from silicon carbide, silicon or gallium nitride and second semiconductor die 330 is a control, driver, current sense and/or temperature detection device and is made from silicon. The electrically insulative layer 322 can electrically isolate the conductive base 302 from each semiconductor die in the multi-chip electronic device 300.

FIG. 3B is a cross-section of the multi-chip electronic device 300 shown in FIG. 3A. As shown in FIG. 3B, the multi-chip electronic device 300 includes an electrically insulative layer 322 attached to conductive base 302. Metal layer 328 can be formed on top of the electrically insulative layer 322. Additionally, the multi-chip electronic device 300 includes a first semi-planar conductor 314. A bottom surface of a second flat portion 326 of the first semi-planar conductor 314 is in contact with the metal layer 328 and a first flat portion 324 of the first semi-planar conductor 314 is attached to a first group 304 of exterior terminals. The multi-chip electronic device 300 can further include a semiconductor die 316. The semiconductor die 316 can be formed on a portion of the metal layer 328. The semiconductor die 316 can include a source terminal on a top surface and a drain terminal on a bottom surface. The first semi-planar conductor 312 electrically connects the drain terminal to the first group 304 of exterior terminals. A second semi-planar conductor 314 electrically connects the source terminal to a second group 306 of exterior terminals. A height of the multi-chip electronic device 300 can be in a range of one to three millimeters with a clearance to a mold surface of 0.1-1.0 mm.

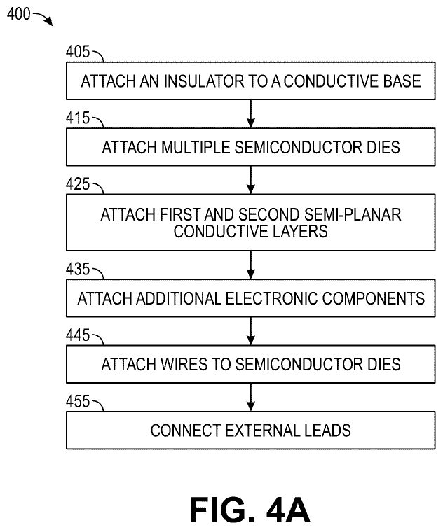

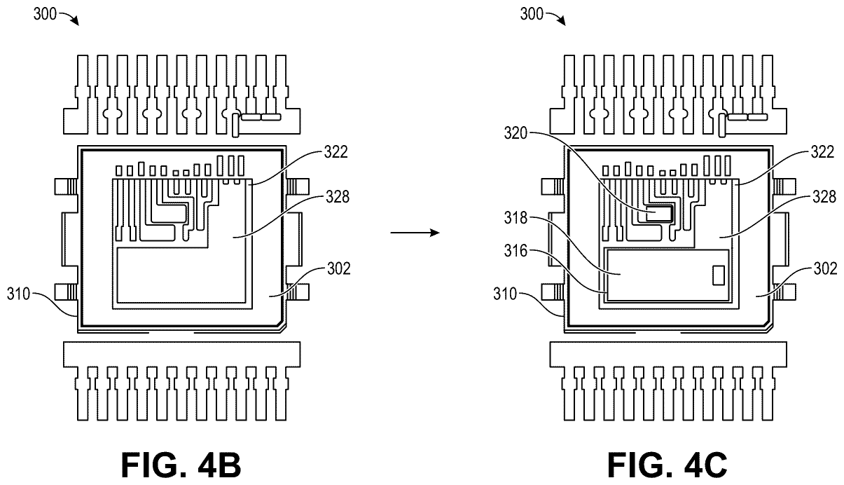

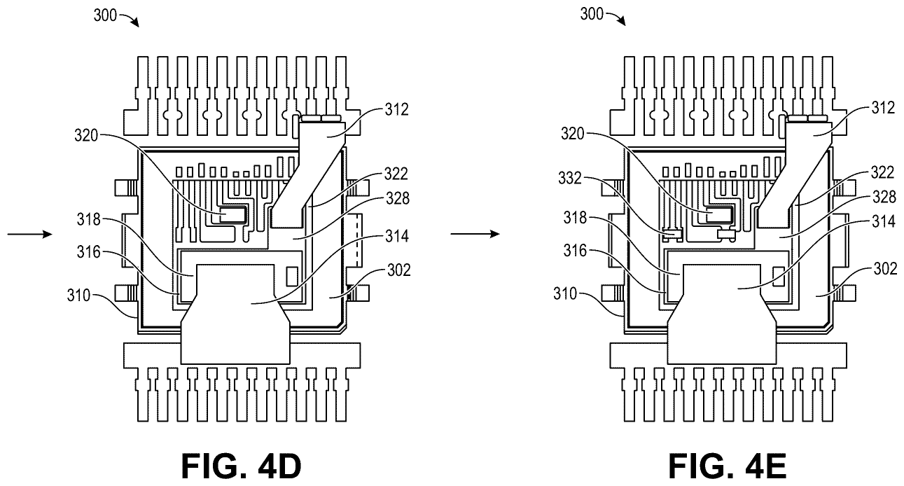

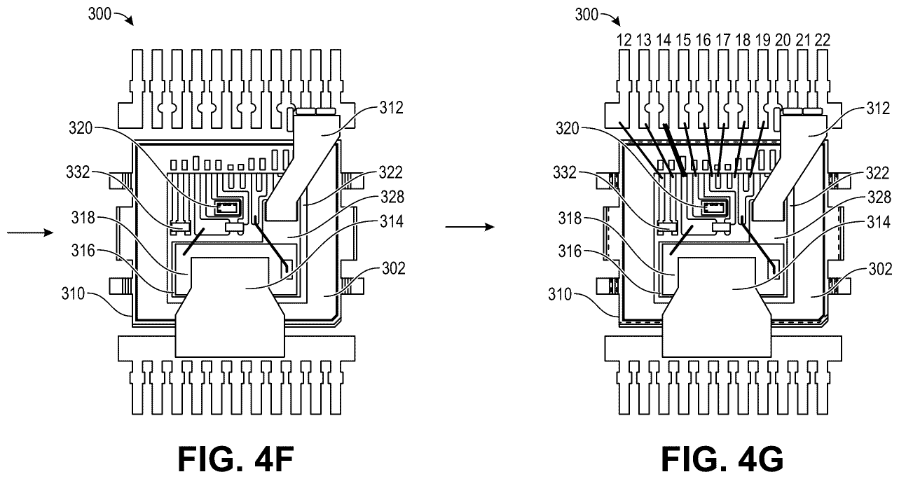

FIG. 4A illustrates steps associated with a method 400 of forming an electronic device 300 according to embodiments of the disclosure. FIGS. 4B-4G illustrate simplified plan views of the formation of the electronic device 300 according to method 400 described in FIG. 4A. Electronic device 300 comprises similar components as described in the figures above, wherein like numerals correspond to like components. Electronic device 300 may be or may include any of the components, features, or characteristics of any of the electronic devices previously described, and the features of electronic device 300 may be included in the electronic devices previously discussed.

Now referring to FIG. 4A, a first step 405 of the method 400 includes soldering or sintering an electrically insulative layer 322 (e.g., a ceramic layer) onto a conductive base 302 (see e.g., FIG. 4B). The electrically insulative layer 322 can include a metal layer 328 that can be patterned. A second step 415 of the method 400, includes the attachment of multiple semiconductor dies, such as first semiconductor die 316 and second semiconductor die 330 (see e.g., FIG. 4C). Examples of the semiconductor dies can include field effect transistors (FET) integrated circuit (IC) or any other suitable type of device which can be fabricated from silicon carbide, silicon and/or gallium nitride. In a third step 425 of the method 400, first and second semi-planar conductors 314, 312 can be attached where the first semi-planar conductor 314 can electrically connect external terminals to a top surface 318 of one of the semiconductor dies and the second semi-planar conductor 312 can connect other external terminals to a portion of the metal trace layer (see e.g., FIG. 4D). A reflow step and/or epoxy cure can occur. In a fourth step 435 of the method 400, additional electronic components 332 (such as capacitors or negative temperature coefficient (NTC) thermistors) are added to the multi-chip electronic device via soldering, epoxy or other suitable method (see e.g., FIG. 4E). In a fifth step 445 of the method 400, wires can be attached (such as gold, aluminum and/or palladium coated copper (PCC) wires) to IC semiconductor dies (see e.g., FIG. 4F). In a sixth step 455 external terminal leads can be connected to the metal layer by wire bonding or other suitable process (see e.g., FIG. 4G).

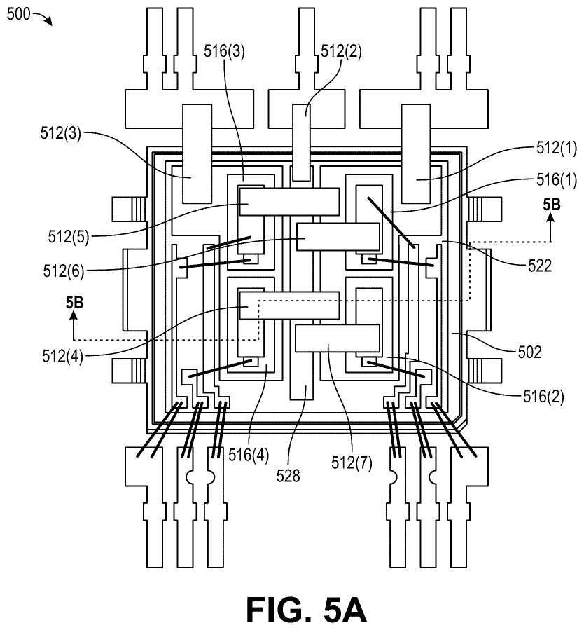

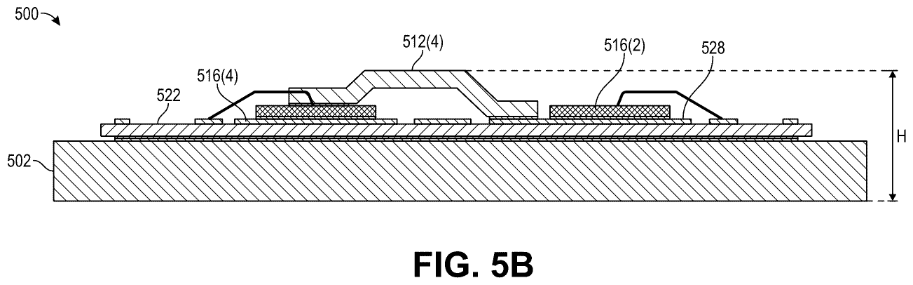

FIG. 5A is a partially transparent top view of an assembled isolated half-bridge electronic device 500 with an electrically isolated heatsink according to some aspects of the present application. FIG. 5B is a cross-section of the assembled isolated half-bridge electronic device 500 shown in FIG. 5A. As shown in FIGS. 5A and 5B, the half-bridge electronic device 500 may be or include any of the components, features, or characteristics of any of the electronic devices, (e.g., single-chip electronic device 100, multi-chip electronic device 300, etc.), previously described in the present disclosure. The half-bridge electronic device 500 can include a conductive base 502, an electrically insulative layer 522, a metal layer 528, semi-planar conductors 512(1)-512(7), and multiple semiconductor dies 516(1)-516(4). The semiconductor dies 516 can be SiC-based. Although seven semi-planar conductors are shown in FIG. 5A, the half-bridge electronic device 500 can include any suitable number of semi-planar conductors. Some of the semi-planar conductors 512(4)-512(7) are oriented in a lateral direction, while others semi-planar conductors 512(1)-512(3) are oriented perpendicular to the lateral direction. Despite the different orientations, all of the semi-planar conductors 512 of the half-bridge electronic device 500 can be formed in a single fabrication step. The electrically insulative layer 522 can electrically insulate the conductive base 502 from each of the semiconductor dies 516(1)-516(4). The half-bridge electronic device 500 can have a thickness h between 1.5 to 3.0 millimeters. The half-bridge electronic device 500 of FIG. 5A is shown to have a footprint of 15 millimeters by 21 millimeters. In other examples, the footprint can have a larger or smaller value.

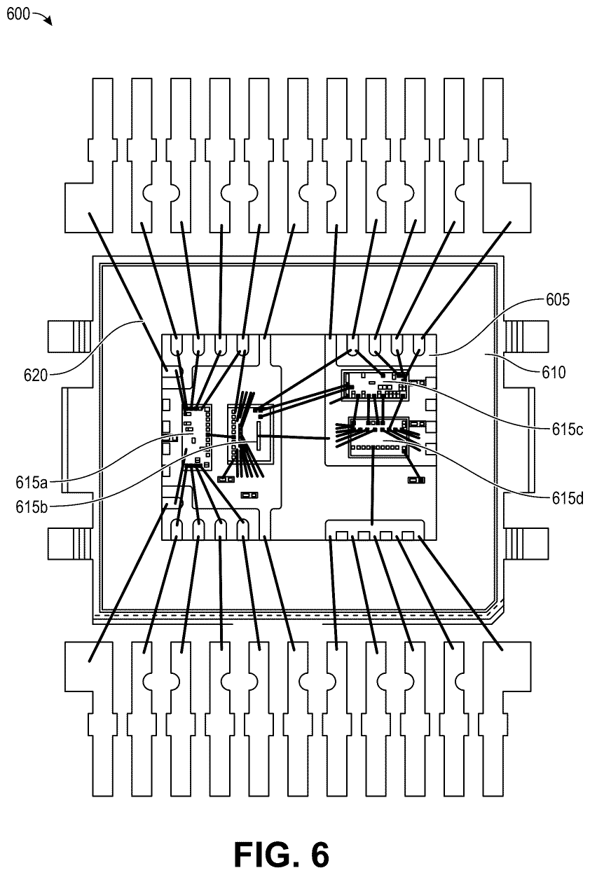

FIG. 6 is a partially transparent top view of an assembled isolated half-bridge electronic device 600 with an electrically isolated heatsink according to some aspects of the present application. The half-bridge electronic device 600 may be or include any of the components, features, or characteristics of any of the electronic devices, (e.g., single-chip electronic device 100, multi-chip electronic device 300, half-bridge electronic device 500, etc.), previously described in the present disclosure. For example, the half-bridge electronic device 600 can include an electrically insulative layer 605 (e.g., a ceramic layer) that can electrically insulate a conductive base 610 from each of several semiconductor dies 615a-615d. The semiconductor dies 615a-615d can be formed from gallium nitride, silicon carbide, silicon or any other suitable semiconductor material. One or more of the wires 620 shown in FIG. 6 can be replaced by one or more semi-planar conductors as described in detail above.

The specification and drawings are, accordingly, to be regarded in an illustrative rather than a restrictive sense. It will, however, be evident that various modifications and changes may be made thereunto without departing from the broader spirit and scope of the disclosure as set forth in the claims.

Other variations are within the spirit of the present disclosure. Thus, while the disclosed techniques are susceptible to various modifications and alternative constructions, certain illustrated embodiments thereof are shown in the drawings and have been described above in detail. It should be understood, however, that there is no intention to limit the disclosure to the specific form or forms disclosed, but on the contrary, the intention is to cover all modifications, alternative constructions and equivalents falling within the spirit and scope of the disclosure, as defined in the appended claims.

The use of the terms “a” and “an” and “the” and similar referents in the context of describing the disclosed embodiments (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening. The phrase “based on” should be understood to be open-ended, and not limiting in any way, and is intended to be interpreted or otherwise read as “based at least in part on,”where appropriate. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate embodiments of the disclosure and does not pose a limitation on the scope of the disclosure unless otherwise claimed. No language in the specification should be construed as indicating any non-claimed element as essential to the practice of the disclosure.

Disjunctive language such as the phrase “at least one of X, Y, or Z,” unless specifically stated otherwise, is otherwise understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present. Additionally, conjunctive language such as the phrase “at least one of X, Y, and Z,” unless specifically stated otherwise, should also be understood to mean X, Y, Z, or any combination thereof, including “X, Y, and/or Z.”

Preferred embodiments of this disclosure are described herein, including the best mode known to the inventors for carrying out the disclosure. Variations of those preferred embodiments may become apparent to those of ordinary skill in the art upon reading the foregoing description. The inventors expect skilled artisans to employ such variations as appropriate, and the inventors intend for the disclosure to be practiced otherwise than as specifically described herein. Accordingly, this disclosure includes all modifications and equivalents of the subject matter recited in the claims appended hereto as permitted by applicable law. Moreover, any combination of the above-described elements in all possible variations thereof is encompassed by the disclosure unless otherwise indicated herein or otherwise clearly contradicted by context.

All references, including publications, patent applications, and patents, cited herein are hereby incorporated by reference to the same extent as if each reference were individually and specifically indicated to be incorporated by reference and were set forth in its entirety herein.

What is claimed is

1. An electronic device comprising:
an electrically conductive base;
a first exterior terminal at an exterior surface of the electronic device;
a second exterior terminal at the exterior surface of the electronic device;
an electrically insulative layer attached to the electrically conductive base;
a first electrical conductor attached to the electrically insulative layer and electrically connected to the first exterior terminal;
a semiconductor die having a first contact at a bottom surface and second contact at a top surface, wherein the semiconductor die is attached to the first electrical conductor such that the first contact is electrically connected to the first electrical conductor;
a second electrical conductor attached to the top surface of the semiconductor die such that the second contact is electrically connected to the second exterior terminal; and
an encapsulant at least partially encapsulating the electrically conductive base, the first exterior terminal, the second exterior terminal, the electrically insulative layer, the first electrical conductor, the semiconductor die, and the second electrical conductor.

2. The electronic device of claim 1, wherein the first contact is a drain terminal of the semiconductor die and the second contact is a source terminal of the semiconductor die.

3. The electronic device of claim 1, wherein the semiconductor die is a transistor.

4. The electronic device of claim 1, wherein the semiconductor die comprises gallium nitride, silicon carbide, or silicon.

5. The electronic device of claim 1, wherein the first electrical conductor is a semi-planar layer of metal, and wherein the second electrical conductor is a semi-planar layer of metal.

6. The electronic device of claim 1, wherein the electrically insulative layer comprises a ceramic.

7. The electronic device of claim 1, wherein a length and a width of a die attach region of the first electrical conductor are larger than a respective length and a respective width of the semiconductor die.

8. The electronic device of claim 1, wherein the semiconductor die includes a kelvin terminal.

9. An electronic device comprising:
a first exterior terminal at an exterior surface of the electronic device;
a second exterior terminal at the exterior surface of the electronic device;
an insulative layer;
a first conductor attached to the insulative layer and electrically connected to the first exterior terminal;
a semiconductor die having a first contact at a bottom surface and a second contact at a top surface, wherein the first contact is attached to the first conductor;
a second conductor attached to the second contact and electrically connected to the second exterior terminal; and
an encapsulant at least partially encapsulating the insulative layer, the first conductor, the semiconductor die, and the second conductor.

10. The electronic device of claim 9, wherein the first contact is a drain terminal of the semiconductor die and the second contact is a source terminal of the semiconductor die.

11. The electronic device of claim 9, wherein the semiconductor die is a transistor.

12. The electronic device of claim 9, wherein the semiconductor die comprises gallium nitride, silicon carbide, or silicon.

13. The electronic device of claim 9, wherein the first conductor is a semi-planar layer of metal, and wherein the second conductor is a semi-planar layer of metal.

14. The electronic device of claim 9, wherein the insulative layer comprises a ceramic.

15. The electronic device of claim 9, wherein a length and a width of a die attach region of the first conductor are larger than a respective length and a respective width of the semiconductor die.

16. The electronic device of claim 9, wherein the semiconductor die includes a kelvin terminal.

17. A method for forming an electronic device, the method comprising:
forming a first terminal;
forming a second terminal;
forming an insulative layer;
forming a first conductor and attaching the first conductor to the insulative layer and to the first terminal;
forming a semiconductor die having a first contact at a bottom surface and a second contact at a top surface;
attaching the first contact to the first conductor;
forming a second conductor;
attaching the second conductor to the second contact and to the second terminal; and
forming a body of the electronic device using an encapsulant that at least partially encapsulates the insulative layer, the first conductor, the semiconductor die, and the second conductor.

18. The method of claim 17, wherein the first contact is a drain terminal of the semiconductor die and the second contact is a source terminal of the semiconductor die.

19. The method of claim 17, wherein the semiconductor die is a transistor.

20. The method of claim 17, wherein the semiconductor die comprises gallium nitride, silicon carbide, or silicon.
